(19) United States
(12) Patent Application Publication
(10) Pub. No.: US 2016/0079514 A1
(43) Pub. Date: Mar. 17, 2016

(54) Method for Manufacturing Piezoelectric Device, Piezoelectric Device, and Piezoelectric Self-Supporting Substrate

(71) Applicant: NGK INSULATORS, LTD., Aichi (JP)

(72) Inventors: Tomoyoshi Tai, Inazawa-city (JP); Yuji Hori, Owariasahi-city (JP)

(73) Assignee: NGK INSULATORS, LTD., Aichi (JP)

(21) Appl. No.: 14/941,794

(22) Filed: Nov. 16, 2015

Related U.S. Application Data
(63) Continuation of application No. PCT/JP2014/061552, filed on Apr. 24, 2014.

(30) Foreign Application Priority Data
May 21, 2013 (JP) 2013-107225

(51) Int. Cl. H01L 41/277; H01L 41/053

(52) U.S. Cl. CPC H01L 41/277; H01L 41/053

(57) ABSTRACT

A piezoelectric substrate 22 and a support substrate 27 are prepared (a), these are joined to each other with an adhesive layer 26 therebetween to form a composite substrate 20 (b), and a surface of the piezoelectric substrate 22 is polished to thin the piezoelectric substrate 22 (c). Then, grooves 28 dividing the piezoelectric substrate 22 into parts having a size for a piezoelectric device are formed by half-dicing the composite substrate 20 (d). By forming the grooves 28, the adhesive layer 26 is exposed in the grooves 28. By immersing the composite substrate in solvent, the adhesive layer 26 is removed by the solvent, and the piezoelectric substrate 22 is detached from the support substrate (e), (f), and a piezoelectric device 10 is obtained using the detached piezoelectric substrate 12 (g).

### BACKGROUND OF THE INVENTION

1. Field of the Invention

The present invention relates to a method for manufacturing a piezoelectric device, a piezoelectric device, and a piezoelectric self-supporting substrate.

2. Description of the Related Art

Hitherto, piezoelectric devices such as crystal oscillators such as QCM (Quartz Crystal Microbalance) sensors and elastic wave devices have been known. In such piezoelectric devices, the sensitivity of the devices increases with decreasing thickness of piezoelectric substrates. So, piezoelectric devices in which piezoelectric substrates are thinned while keeping the strength of the piezoelectric substrates are proposed. For example, a crystal oscillator in which crystal as a piezoelectric substrate is thinned except the peripheral part thereof is described in Patent Literature 1.

FIG. 6 is a schematic sectional view of the crystal oscillator described in Patent Literature 1. The crystal oscillator 90 includes a crystal plate 92, electrodes 94 and 95 that are respectively formed on the upper and lower surface of the crystal plate 92, and a breakage prevention film 96 that covers the upper surface of the crystal plate 92 and the surface of the electrode 94 and that is formed of resin. In the crystal oscillator 90, a hole 92b is formed by etching in the lower surface of the crystal plate 92 except for the peripheral part 92a. The electrode 95 is formed on the bottom 92c of the hole 92b. PTL1 describes that, owing to this configuration, in the crystal oscillator 90, it is possible to reduce the thickness of the central part of the crystal plate 92 (=the distance between the electrodes 94 and 95) while keeping the strength of the crystal plate 92 with the peripheral part 92a and to improve the detection sensitivity. PTL1 also describes that since having the breakage prevention film 96, the crystal oscillator 90 can be prevented from being broken during transportation, use, and the like.

### CITATION LIST

### Patent Literature

PTL 1: Japanese Unexamined Patent Application Publication No. 2003-222581

### SUMMARY OF THE INVENTION

However, the crystal oscillator shown in FIG. 6 has a problem that since the crystal plate 92 has the peripheral part 92a, that is, a thick part, oscillation leakage to the peripheral part 92a occurs, and the Q-value as a piezoelectric device deteriorates. When trying to make a piezoelectric device having a piezoelectric substrate not having the peripheral part 92a by a conventional manufacturing method in which a piezoelectric substrate single plate is thinned by polishing, the piezoelectric substrate may crack during polishing or in the subsequent manufacturing step, and there is a limit to the reduction of thickness.

The present invention is made to solve such a problem, and it is the main object of the present invention to thin a piezoelectric substrate while suppressing the deterioration of characteristics in a piezoelectric device.

### Solution to Problem

To achieve the above main object, the present invention takes the following measures.

A method for manufacturing a piezoelectric device of the present invention includes the steps of:

(a) preparing a piezoelectric substrate and a support substrate;

(b) joining the piezoelectric substrate and the support substrate with an adhesive layer therebetween to form a composite substrate;

(c) polishing a surface of the piezoelectric substrate on the side opposite to a joint surface with the support substrate to thin the piezoelectric substrate;

(d) dicing the composite substrate or half-dicing the composite substrate from the surface of the piezoelectric substrate on the side opposite to the joint surface with the support substrate and thereby dividing the piezoelectric substrate into parts having a size for a piezoelectric device;

(e) immersing the composite substrate after the dicing or the half dicing is performed in solvent, thereby removing the adhesive layer using the solvent, and detaching the piezoelectric substrate from the support substrate; and

(f) obtaining a piezoelectric device using the piezoelectric substrate detached from the support substrate.

A piezoelectric device of the present invention is manufactured by the above-described method for manufacturing a piezoelectric device of the present invention.

A piezoelectric self-supporting substrate of the present invention has a thickness of 0.2 ∝m or more and 5 ∝m or less, a length of 0.1 mm or more, a width of 0.1 mm or more, and a TTV (Total Thickness Variation) of 0.1 ∝m or less.

### Advantageous Effects of Invention

In the method for manufacturing a piezoelectric device of the present invention, first, a prepared piezoelectric substrate and support substrate are joined to each other with an adhesive layer therebetween, and a surface of the piezoelectric substrate on the side opposite to the joint surface with the support substrate is polished to thin the piezoelectric substrate. Since the piezoelectric substrate is polished in a state joined with the support substrate, cracking or the like of the piezoelectric substrate during polishing is suppressed, and the piezoelectric substrate can be made much thinner. Next, the piezoelectric substrate is divided into parts having a size for a piezoelectric device by dicing the composite substrate or half-dicing the composite substrate from the surface of the piezoelectric substrate on the side opposite to the joint surface with the support substrate. Then, the composite substrate is immersed in solvent, the adhesive layer is removed by the solvent, and the piezoelectric substrate is detached from the support substrate. A piezoelectric device is obtained using the detached piezoelectric substrate. As described above, the exposed area of the adhesive layer is increased by dicing or half dicing. Therefore, when the composite substrate is immersed in the solvent, the solvent can efficiently remove the adhesive layer. The piezoelectric substrate is divided into parts having a size for a piezoelectric device in advance by dicing or half dicing. Therefore, by removing the adhesive layer and detaching from the support substrate, the piezoelectric substrate after detachment can be used as it is to make a piezoelectric device. Therefore, compared to a case where a single piezoelectric substrate is diced after detachment, cracking or the like hardly occurs in the piezoelectric substrate even when the piezoelectric substrate after detachment is thin. By such a manufacturing method, a piezoelectric self-supporting substrate for a piezoelectric device that does not have a thick part like the peripheral part 92a of FIG. 6 and that is thinner can be obtained. As a result, a piezoelectric device manufactured by the method for manufacturing a piezoelectric device of the present invention can be improved in sensitivity while suppressing the deterioration of characteristics, for example, due to the existence of the peripheral part 92a. The piezoelectric self-supporting substrate means a piezoelectric substrate not supported by a support substrate or the like.

A piezoelectric self-supporting substrate of the present invention has a thickness of 0.2 ∝m or more and 5 ∝m or less, a length of 0.1 mm or more, a width of 0.1 mm or more, and a TTV of 0.1 ∝m or less. Such a piezoelectric self-supporting substrate does not have a thick part like the peripheral part 92a and is thinner. Therefore, by using this, a thin (highly sensitive) piezoelectric device can be obtained while suppressing the deterioration of characteristics. The piezoelectric self-supporting substrate of the present invention can be only obtained by the steps (a) to (e) of the above-described method for manufacturing a piezoelectric device of the present invention. The wording “the thickness of the piezoelectric self-supporting substrate is 5 ∝m or less” means that there is no part where the thickness of the piezoelectric self-supporting substrate exceeds 5 ∝m (there is no part where the thickness of the piezoelectric self-supporting substrate exceeds 5 ∝m, for example, like the peripheral part 92a of FIG. 6).

### BRIEF DESCRIPTION OF DRAWINGS

FIG. 1 is a sectional view schematically showing a piezoelectric device 10 of this embodiment.

FIGS. 2A-2F illustrate perspective views schematically showing the manufacturing steps of the piezoelectric device 10.

FIGS. 3A-3G illustrate sectional views schematically showing the manufacturing steps of the piezoelectric device 10.

FIGS. 4A-4G are sectional views schematically showing the manufacturing steps of a piezoelectric device 10 of a modification in this case.

FIGS. 5A-5G are sectional views schematically showing the manufacturing steps of a piezoelectric device 10 of a modification in this case.

FIG. 6 is a schematic sectional view of the crystal oscillator of conventional configuration.

### DESCRIPTION OF PREFERRED EMBODIMENTS

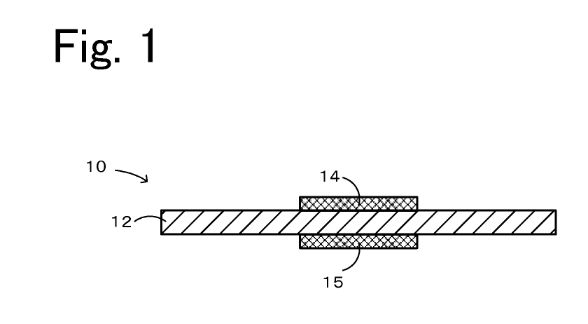

Next, embodiments of the present invention will be described with reference to the drawings. FIG. 1 is a sectional view schematically showing a piezoelectric device 10 of this embodiment. The piezoelectric device 10 includes a piezoelectric substrate 12, a first electrode 14 formed on a first surface (the upper surface in FIG. 1) of the piezoelectric substrate 12, and a second electrode 15 formed on a second surface (the lower surface in FIG. 1) of the piezoelectric substrate 12. The piezoelectric device 10 is a QCM sensor in this embodiment. However, the piezoelectric device 10 may be any other piezoelectric device such as an elastic wave device.

The piezoelectric substrate 12 is a substrate formed of a piezoelectric body. Examples of materials for the piezoelectric substrate 12 include lithium tantalate (LT), lithium niobate (LN), lithium niobate-lithium tantalate solid solution single crystal, crystal, lithium borate, zinc oxide, aluminum nitride, langasite (LGS), and langatate (LGT). The piezoelectric substrate 12 is preferably a single crystal substrate. When the piezoelectric substrate 12 is a single crystal substrate, the Q-value as a piezoelectric device can be improved. In this embodiment, since the piezoelectric device 10 is a QCM sensor, the piezoelectric substrate 12 is formed of crystal. For example, when the piezoelectric device 10 is an elastic wave device, the piezoelectric substrate 12 is preferably formed of LT or LN. The reason is that since having a high propagation rate of a surface acoustic wave and a high electromechanical coupling coefficient, LT and LN are suitably used for a high-frequency and wideband-frequency elastic wave device. The piezoelectric substrate 12 is, for example, but not limited to, 0.1 mm×0.1 mm or more. The piezoelectric substrate 12 may be, for example, 1 mm×1 mm or more, 2 mm×2 mm or more, 10 mm×10 mm or less, 8 mm×8 mm or less, or 5 mm×5 mm or less. When obtaining the piezoelectric substrate 12 by dicing or half dicing, chipping may occur in the edge part. If the chip size of the piezoelectric substrate 12 is too small, chipping has a significant impact. Therefore, the piezoelectric substrate 12 is preferably 1 mm×1 mm or more. From the viewpoint of size reduction of the piezoelectric device 10, the piezoelectric substrate 12 is preferably 5 mm×5 mm or less. The thickness of the piezoelectric substrate 12 is preferably 0.2 ∝m or more and 5 ∝m or less. The wording “the thickness of the piezoelectric substrate 12 is 5 ∝m or less” means that there is no part where the thickness of the piezoelectric substrate 12 exceeds 5 ∝m. The smaller the thickness of the piezoelectric substrate 12, the higher the sensitivity (for example, S/N ratio) of the piezoelectric device 10. The thickness of the piezoelectric substrate 12 is preferably 4 ∝m or less, and more preferably 3 ∝m or less. When the thickness of the piezoelectric substrate 12 is 0.2 ∝m or more, the piezoelectric substrate 12 can easily support itself. The TTV (Total Thickness Variation) of the piezoelectric substrate 12 is preferably 0.1 ∝m or less, and more preferably 0.05 ∝m or less. The first and second surfaces (the upper and lower surfaces in FIG. 1) of the piezoelectric substrate 12 are preferably as flat as possible to suppress the deterioration of Q-value and the generation of spurious. For example, the arithmetical mean roughness Ra of the first and second surfaces (both the upper and lower surfaces) of the piezoelectric substrate 12 is preferably 1 nm or less, more preferably 0.5 nm or less, even more preferably 0.1 nm or less. The piezoelectric substrate 12 may have a breakage prevention film that covers the first surface of the piezoelectric substrate 12 and the surface of the electrode 14 and that is formed of resin. However, when the piezoelectric substrate 12 has a breakage prevention film, that is, a reinforcement, the Q-value as a piezoelectric device is prone to deteriorate. Therefore, the piezoelectric substrate 12 preferably does not have a breakage prevention film. Likewise, the piezoelectric substrate 12 is preferably not supported by a support substrate or the like. When the piezoelectric substrate 12 is a piezoelectric self-supporting substrate not having a breakage prevention film, a support substrate, and the like, the deterioration of Q-value as a piezoelectric device can be suppressed.

The electrodes 14 and 15 are electrodes of a QCM sensor, and are formed, for example, in a shape that is circular when the piezoelectric substrate 12 is viewed from above and below in FIG. 1. The electrodes 14 and 15 are opposite to each other in the vertical direction in FIG. 1 with the piezoelectric substrate 12 therebetween. By applying an alternating electric field between the electrodes 14 and 15, oscillation of a predetermined frequency is excited. When a substance adheres to the surface of one of the electrodes 14 and 15 and the mass changes, the frequency of oscillation changes. Therefore, the piezoelectric device 10 functions as a QCM sensor that can detect the presence or absence and the amount of a predetermined substance on the basis of this change of frequency. A QCM sensor can be used, for example, as a biosensor or a sensor that measures the film thickness in a deposition system. When using as a biosensor, a sensitive film for facilitating catching a substance to be detected is formed on the surface of at least one of the electrodes 14 and 15. Leads (not shown) formed on the first and second surfaces of the piezoelectric substrate 12 may be connected to the electrodes 14 and 15. A plurality of electrodes 14 and a plurality of electrodes 15 may be formed on one piezoelectric substrate 12.

The presence or absence and the shape of the electrodes 14 and 15 can be appropriately selected according to the use of the piezoelectric device 10. For example, when the piezoelectric device 10 is an elastic wave device, the piezoelectric device 10 may not include the electrodes 14 and 15, and in place of the electrode 14, an IDT electrode (also referred to as a comb-shaped electrode or an interdigital electrode) and a reflective electrode may be formed on the first surface of the piezoelectric substrate 12.

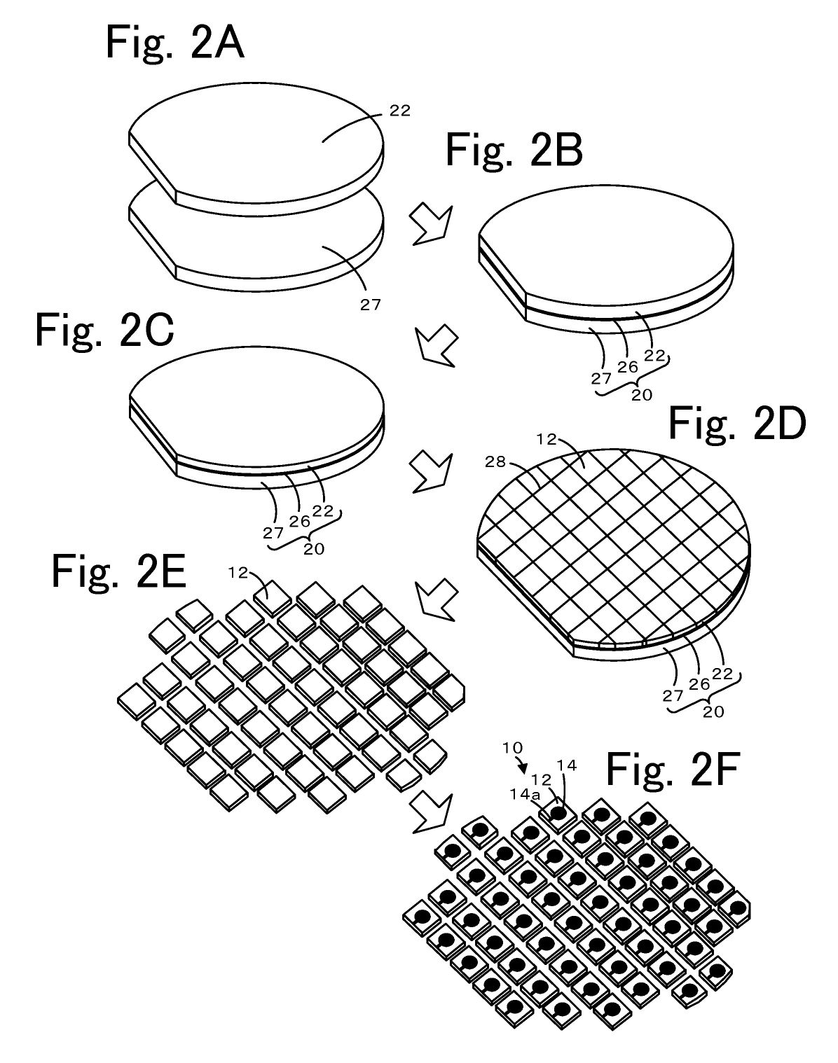

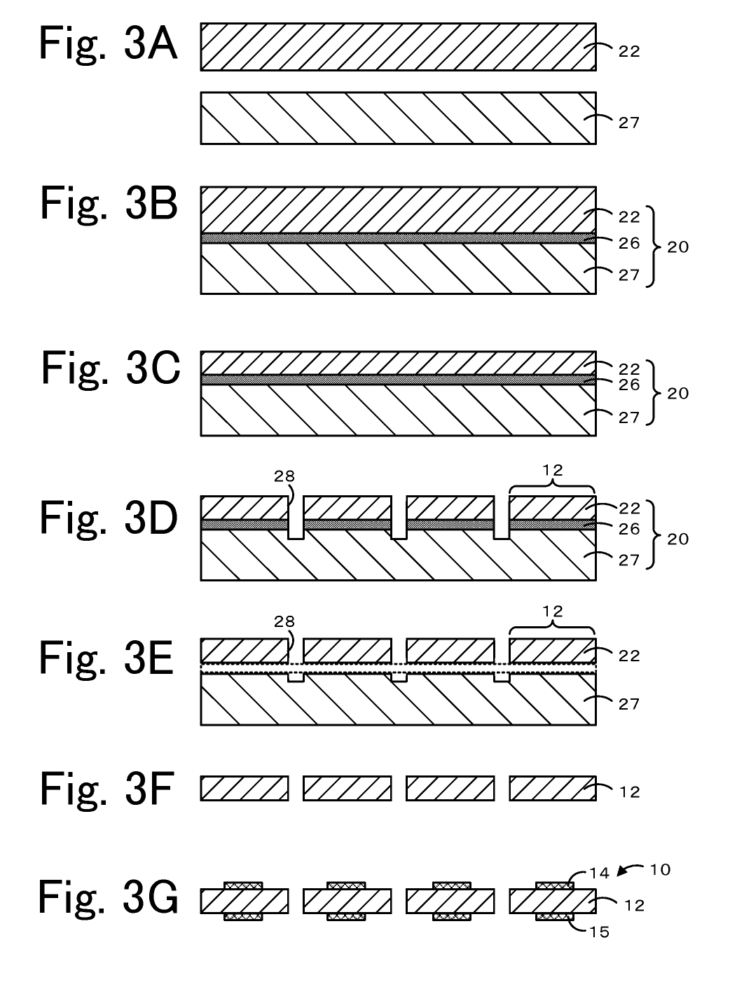

Next, a method for manufacturing such a piezoelectric device 10 will be described below with reference to FIGS. 2A-2F and 3A-3G. FIGS. 2A-2F illustrate perspective views schematically showing the manufacturing steps of the piezoelectric device 10. FIGS. 3A-3G illustrate sectional views schematically showing the manufacturing steps of the piezoelectric device 10.

First, the step (a) of preparing a piezoelectric substrate 22 and a support substrate 27 is performed (FIG. 2A and FIG. 3A), and the step (b) of bonding the piezoelectric substrate 22 and the support substrate 27 with an adhesive layer 26 therebetween to form a composite substrate 20 is performed (FIG. 2B and FIG. 3B). The piezoelectric substrate 22 undergoes the manufacturing steps of the piezoelectric device 10 to become the above-described piezoelectric substrates 12. The size of the piezoelectric substrate 22 is, for example, but not limited to, 50 to 150 mm in diameter and 50 to 500 ∝m in thickness. The support substrate 27 is a substrate that supports the piezoelectric substrate 22 during the polishing of the piezoelectric substrate 22 described later. Examples of the materials for the support substrate 27 include crystal, LT, LN, silicon, glass such as borosilicate glass and quartz glass, and ceramics such as aluminum nitride and alumina. The size of the support substrate 27 is, for example, but not limited to, 50 to 150 mm in diameter and 100 to 600 ∝m in thickness. The adhesive layer 26 can be formed, for example, of adhesive that has an adhesive strength withstanding a processing load such as that of the polishing of the piezoelectric substrate 22 described later and that can be removed using solvent described later. The adhesive layer 26 is formed, for example, of organic adhesive. The materials for the adhesive layer 26 include epoxy, acrylic, and polyimide.

A surface of the piezoelectric substrate 22 prepared in the step (a) that serves as a joint surface with the support substrate 27 in the step (b) (the lower surface in FIGS. 3A-3G) is preferably already mirror-polished. By doing so, as described above, the deterioration of Q-value and the generation of spurious in the piezoelectric device 10 can be suppressed. Specifically, the arithmetical mean roughness Ra of a surface of the piezoelectric substrate 22 that serves as a joint surface with the support substrate 27 is preferably 1 nm or less, more preferably 0.5 nm or less, and even more preferably 0.1 nm or less owing to mirror polishing. A surface of the prepared piezoelectric substrate 22 that serves as a joint surface with the support substrate 27 in the step (b) (the lower surface in FIGS. 3A-3G) may be mirror-polished in the step (a).

Next, the step (c) of polishing a surface of the piezoelectric substrate 22 on the side opposite to the joint surface with the support substrate 27 to thin the piezoelectric substrate 22 is performed (FIG. 2C and FIG. 3C). As described above, the thinner the piezoelectric substrate 22, the higher the sensitivity (for example, S/N ratio) of the piezoelectric device 10 after manufacturing. Specifically, it is preferable to perform polishing until the thickness of the piezoelectric substrate 22 becomes 0.2 ∝m to 5 ∝m. The thickness is more preferably 4 ∝m or less, and even more preferably 3 ∝m or less. The LTV (Local Thickness Variation) of the piezoelectric substrate 22 after polishing is preferably 0.1 ∝m or less on average, and more preferably 0.05 ∝m or less on average. The LTV of the piezoelectric substrate after polishing is measured in each area of the piezoelectric substrate 22 that has the size of the piezoelectric substrate 12 of the piezoelectric device 10 to be manufactured (chip size). The average value of the measured LTVs is used as the average value of the LTV of the piezoelectric substrate 22. In order for the arithmetical mean roughness Ra to satisfy the same numerical range as that of the above-described surface of the piezoelectric substrate 22 that serves as a joint surface, it is preferable to mirror-polish a surface of the piezoelectric substrate 22 on the side opposite to the joint surface with the support substrate 27 (the upper surface in FIGS. 3A-3G) in the step (c).

Next, the step (d) is performed (FIG. 2D and FIG. 3D) in which grooves 28 dividing the piezoelectric substrate 22 into parts having a size for a piezoelectric device are formed by half-dicing the composite substrate 20 from the surface of the piezoelectric substrate 22 on the side opposite to the joint surface with the support substrate 27, and the adhesive layer 26 is exposed in the grooves 28. The grooves 28 are formed, for example, in two directions substantially perpendicular to each other as shown in FIG. 2D. The interval between the grooves 28 parallel to each other is appropriately determined according to the chip size of the piezoelectric device 10 to be manufactured (for example, 0.1 mm or more and 10 mm or less). The width (the length in the horizontal direction in FIGS. 3A-3G) of the grooves 28 is appropriately determined so that solvent used in a step described later can easily enter the grooves 28 (for example, several tens of ∝m to one hundred and several tens of ∝m). The grooves 28 are formed by half-dicing the composite substrate 20, and penetrate at least the piezoelectric substrate 22 of the composite substrate 20 in the thickness direction. The adhesive layer 26 is thereby exposed in the grooves 28. In FIG. 3D, the grooves 28 penetrate through the piezoelectric substrate 22 and the adhesive layer 26 and cut into the support substrate 27. However, the grooves 28 may penetrate through the piezoelectric substrate 22 and may not cut into the support substrate 27 (the grooves 28 may not reach the support substrate 27). Since the grooves 28 are formed so as not to penetrate through the support substrate 27, the piezoelectric substrate 22 is divided into a plurality of substantially rectangular chips (piezoelectric substrates 12) by the grooves 28. However, since the piezoelectric substrates 12 are joined with the support substrate 27 by the adhesive layer 26, the state of the composite substrate 20 is almost kept.

After performing the half dicing of the step (d), the step (e) is performed (FIG. 2E and FIGS. 3E and 3F) in which the composite substrate 20 is immersed in solvent, the adhesive layer 26 is removed by the solvent, and the piezoelectric substrate 22 (plurality of piezoelectric substrates 12) are detached from the support substrate 27. Since the grooves 28 are formed, the solvent enters the grooves 28 when the composite substrate 20 is immersed in the solvent. Therefore, compared, for example, to a case where the adhesive layer 26 is exposed only on the side surface (the left and right end faces in FIGS. 3A-3G) of the composite substrate 20, the contact area between the adhesive layer 26 and the solvent is large, and therefore the adhesive layer 26 can be removed in a shorter time. Since the adhesive layer 26 is removed, the piezoelectric substrate 22 and the support substrate 27 are separated from each other (FIG. 3E), and the piezoelectric substrate 22 (plurality of piezoelectric substrates 12) can be detached from the support substrate 27 (FIG. 3F). The piezoelectric substrates 12 as piezoelectric self-supporting substrates can be thereby obtained. Any solvent can be used in the step (e) as long as it can remove (dissolve) the adhesive layer 26. It is preferable to use solvent that does not damage the piezoelectric substrate 22. For example, alkaline solution such as potassium hydroxide, and organic solvent such as acetone can be used as solvent. It is preferable to use alkaline solution so that the adhesive layer 26 can be removed in a shorter time. In the step (e), the composite substrate 20 and the solvent may be heated (for example, to 60 to 80° C.) so that the adhesive layer 26 can be removed in a shorter time. It is preferable that the values of TTV and arithmetical mean roughness Ra of the piezoelectric substrates 12 obtained in the step (e) satisfy the numerical ranges described above in relation to the piezoelectric substrate 12 of FIG. 1.

Then, the step (f) of obtaining a large number of piezoelectric devices 10 using the piezoelectric substrates 12 detached from the support substrate 27 is performed (FIG. 2F and FIG. 3G). Since the piezoelectric devices 10 are QCM sensors in this embodiment, the above-described electrodes 14 and 15 are respectively formed on the first and second surfaces (the upper and lower surfaces in FIG. 3G) of each of the plurality of piezoelectric substrates 12. A lead 14a connected to the electrode 14 (see FIG. 2F) and a lead (not shown) connected to the electrode 15 are formed. The electrodes 14 and 15, the lead 14a, and the like may be formed, for example, by using photolithographic technique, or by physical vapor deposition method or chemical vapor deposition method. Through the above manufacturing steps, the above-described large number of piezoelectric devices 10 are obtained.

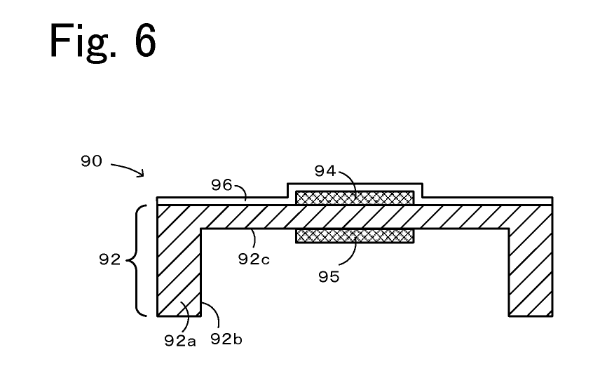

According to this embodiment described above, a prepared piezoelectric substrate 22 and support substrate 27 are joined to each other with an adhesive layer 26 therebetween, and a surface of the piezoelectric substrate 22 on the side opposite to the joint surface with the support substrate 27 is polished to thin the piezoelectric substrate 22. Since the piezoelectric substrate 22 is polished in a state joined with the support substrate 27, cracking or the like of the piezoelectric substrate 22 during polishing is suppressed, and the piezoelectric substrate 22 can be made much thinner. Next, grooves 28 dividing the piezoelectric substrate 22 into parts having a size for a piezoelectric device are formed by half-dicing the composite substrate 20 from the surface of the piezoelectric substrate 22 on the side opposite to the joint surface with the support substrate 27. The adhesive layer 26 is exposed in the grooves 28 by forming the grooves 28. Then, the composite substrate 20 is immersed in solvent, the adhesive layer 26 is removed by the solvent, and the piezoelectric substrate 22 is detached from the support substrate 27. Piezoelectric devices are obtained using the detached piezoelectric substrate 22 (piezoelectric substrates 12). As described above, a plurality of grooves 28 are formed by half dicing, the adhesive layer 26 is exposed in the grooves 28, and the exposed area is increased. Therefore, when the composite substrate 20 is immersed in the solvent, the solvent entering the grooves 28 can efficiently remove the adhesive layer 26. The piezoelectric substrate 22 is divided into parts having a size for a piezoelectric device in advance by the grooves 28. Therefore, by removing the adhesive layer 26 and detaching from the support substrate 27, the piezoelectric substrates 12 after detachment can be used as they are to make piezoelectric devices. Therefore, compared to a case where a single piezoelectric substrate 12 is diced after detachment, cracking or the like is unlikely to occur in the piezoelectric substrates 12 even when the piezoelectric substrates 12 after detachment are thin. By such a manufacturing method, a piezoelectric substrate 12 that does not have a thick part like the peripheral part 92a of FIG. 6, that is thinner, and that is a piezoelectric self-supporting substrate for a piezoelectric device can be obtained. As a result, a piezoelectric device 10 obtained using this piezoelectric substrate 12 can be improved in sensitivity while suppressing the deterioration of characteristics, for example, due to the existence of the peripheral part 92a.

When a surface of the piezoelectric substrate 22 prepared in the step (a) that serves as a joint surface with the support substrate 27 in the step (b) (the lower surface in FIGS. 3A-3G) is already mirror-polished, or when a surface of the prepared piezoelectric substrate 22 that serves as a joint surface with the support substrate 27 in the step (b) is mirror-polished, the deterioration of Q-value and the generation of spurious in the piezoelectric device 10 can be suppressed. When, as in the crystal oscillator 90 of FIG. 6, the thickness of the central part of a crystal plate 92 is thinned by forming a hole 92b by etching, the surface of the bottom 92c is likely to be relatively rough owing to etching. Owing to the structure in which the peripheral part 92a exists, it is difficult to mirror-polish the bottom 92c after etching. In the method for manufacturing a piezoelectric device of this embodiment, the second surface (the lower surface in FIGS. 3A-3G) of the piezoelectric substrate 22 is only subjected to bonding by the adhesive layer 26 and removal of the adhesive layer 26, and can be therefore mirror-polished in advance.

The present invention is not limited to the above-described embodiment, and it goes without saying that the present invention may be embodied in various forms without departing from the technical scope of the present invention.

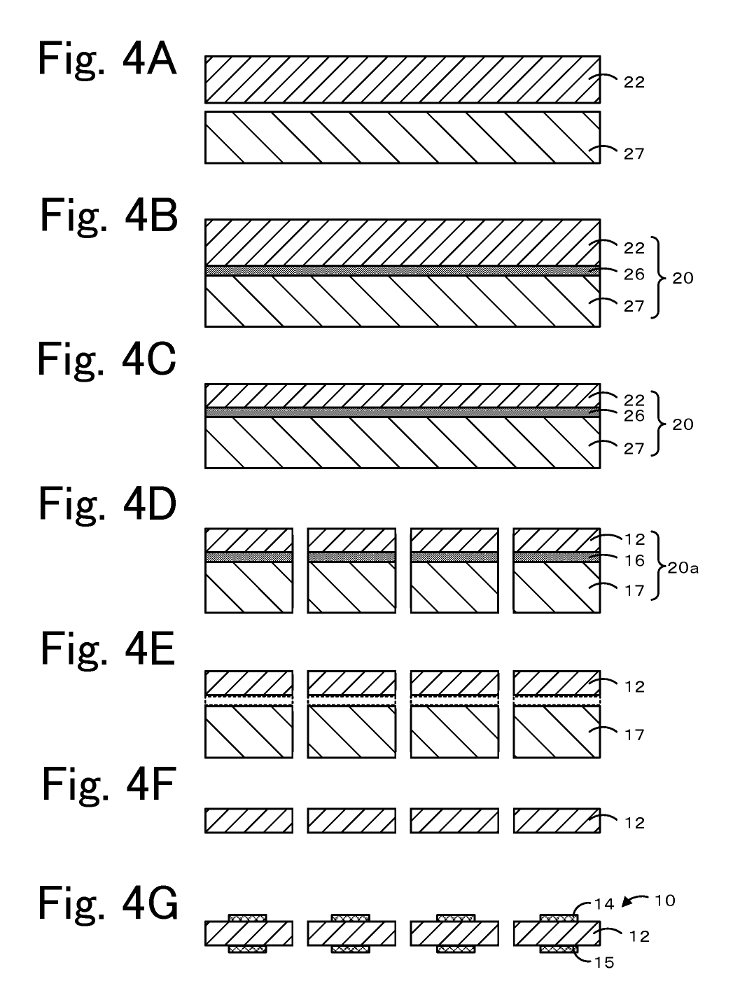

For example, although, in the above-described embodiment, the grooves 28 are formed by half dicing in the step (d), the composite substrate 20 may be diced. FIGS. 4A-4G are sectional views schematically showing the manufacturing steps of a piezoelectric device 10 of a modification in this case. FIG. 4A to 4C, 4F, and 4G (that is, except for the steps (d) and (e)) are the same as those of FIGS. 3A-3G, and so the detailed description thereof will be omitted. As shown in FIG. 4D, in the manufacturing method of a piezoelectric device 10 of this modification, in the step (d), instead of forming the grooves 28 by half-dicing the composite substrate 20, the composite substrate 20 is divided by dicing. That is, in the above-described embodiment, the grooves 28 are formed so as not to penetrate through the support substrate 27, whereas in the manufacturing method of this modification shown in FIGS. 4A-4G, the grooves 28 penetrate through the support substrate 27, and divide not only the piezoelectric substrate 22 but the whole composite substrate 20 into a plurality of parts. The piezoelectric substrate 22, the adhesive layer 26, and the support substrate 27 are respectively divided by dicing into piezoelectric substrates 12, adhesive layers 16, and support substrates 17, and the composite substrate 20 is divided into a plurality of composite substrates 20a each consisting of a piezoelectric substrate 12, an adhesive layer 16, and a support substrate 17. The size of the composite substrate 20a (piezoelectric substrates 12) after the division by dicing is appropriately determined according to the chip size of the piezoelectric device 10 to be manufactured as in the above-described embodiment. After performing the step (d), as in the above-described embodiment, in the step (e), the plurality of composite substrates 20a after division are immersed in solvent, the adhesive layers 16 are removed, and the piezoelectric substrates 12 are detached from the support substrates 17 (FIGS. 4E and 4F). Thus, in the manufacturing steps of a piezoelectric device 10 of this modification, by dicing the composite substrate 20 in the step (d), the exposed area of the adhesive layers 16 after dicing can be increased compared to the adhesive layer 26 before dicing. Therefore, the contact area between the adhesive layers 16 and solvent in the step (e) is larger, and the adhesive layers 16 can be removed in a shorter time in the step (e). The piezoelectric substrate 22 is divided into piezoelectric substrates 12 having a size for a piezoelectric device in advance by dicing. Therefore, by removing the adhesive layers 16 and detaching from the support substrates 17, the piezoelectric substrates after detachment can be used as they are to make piezoelectric devices. In the step (d), the dicing of the composite substrate 20 may be performed from the piezoelectric substrate side or the support substrate side. However, it is preferable to perform from the piezoelectric substrate side.

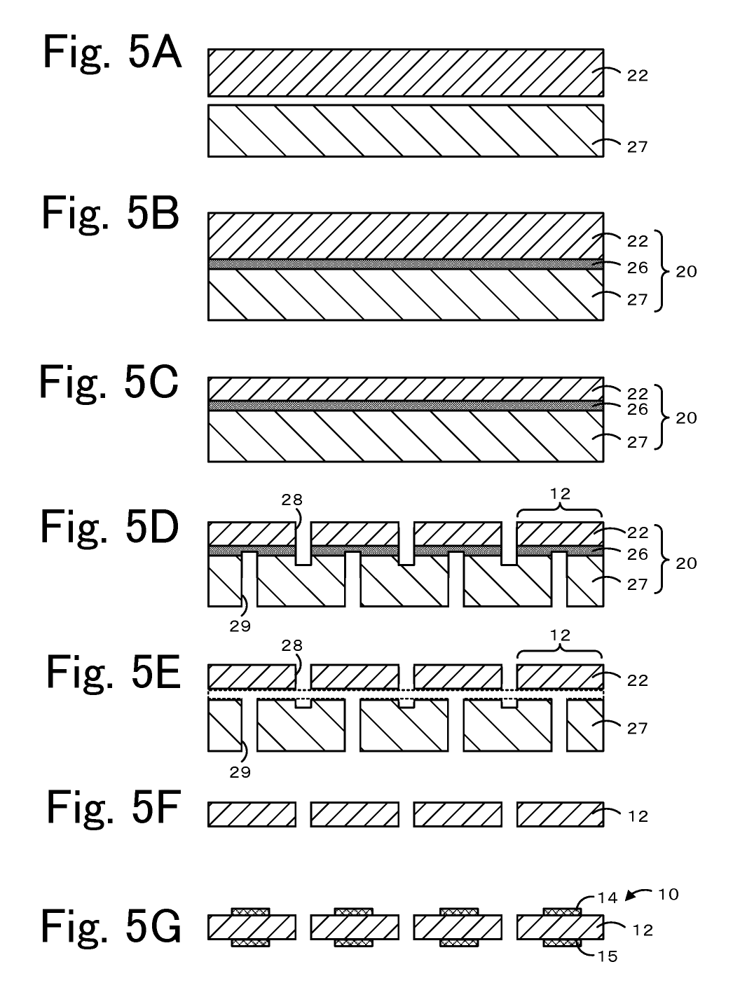

In the above-described embodiment, the grooves 28 are formed in the step (d). In addition to this, holes 29 may be formed in the support substrate 27 from a surface of the support substrate 27 on the side opposite to the joint surface with the piezoelectric substrate 22, and the adhesive layer 26 may be exposed in the holes 29. FIGS. 5A-5G are sectional views schematically showing the manufacturing steps of a piezoelectric device 10 of a modification in this case. FIG. 5A to 5C, 5F, and 5G (that is, except for the steps (d) and (e)) are the same as those of FIGS. 3A-3G, and so the detailed description thereof will be omitted. As shown in FIG. 5D, in the manufacturing method of a piezoelectric device 10 of this modification, in the step (d), holes 29 are formed in the support substrate 27 from the lower surface of the support substrate 27, and the adhesive layer 26 is exposed in the holes 29. The holes 29 may be formed by half dicing as with the grooves 28, or may be formed by other methods such as etching. Either of the formation of the holes 29 and the formation of the grooves 28 may be carried out first. In FIG. 5D, the holes 29 penetrate through the support substrate 27 and cut into the adhesive layer 26. The holes 29 are formed so as not to cut into the piezoelectric substrate 22 (such that the holes 29 do not reach the piezoelectric substrate 22). After performing the step (d), as in the above-described embodiment, in the step (e), the composite substrate 20 is immersed in solvent, and the piezoelectric substrate 22 (plurality of piezoelectric substrates 12) are detached from the support substrate 27 (FIGS. 5E and 5F). Since not only the grooves 28 from the piezoelectric substrate 22 side but also the holes 29 from the support substrate 27 side are formed, the contact area between the adhesive layer 26 and solvent in the step (e) is larger. Therefore, the adhesive layers 26 can be removed in a shorter time in the step (e). Since the holes 29 are provided in the support substrate 27, unlike the grooves 28, regardless of the chip size of the piezoelectric devices 10, any size and number of the holes 29 can be formed. For example, the holes 29 may be formed so as to be located directly below the grooves 28 in FIGS. 5A-5G. In this case, the holes 29 and the grooves 28 may communicate with each other. The holes 29 may be formed such that the composite substrate 20 is divided by the holes 29 and the grooves 28. That is, as in the step (d) of the modification described with reference to FIG. 4D, holes 29 communicating with the grooves 28 may be formed so that the composite substrate 20 is divided into a plurality of composite substrates 20a. Alternatively, all of the parts of the support substrate 27 directly below, in FIGS. 5A-5G, the piezoelectric substrate 22 divided by the grooves 28 (piezoelectric substrates 12) may be removed so as to form holes 29. When such holes 29 are formed, the piezoelectric substrates 12 (and part of the adhesive layer 26) directly above the holes 29 are separated from the composite substrate 20. When the separated piezoelectric substrates 12 are immersed in solvent in the step (e), the adhesive layer 26 is removed, and the piezoelectric substrates 12 can be used to make piezoelectric devices 10. Also in the manufacturing steps of a piezoelectric device 10 of the modification described with reference to FIGS. 4A-4G, holes 29 may be formed and the adhesive layer 16 may be exposed in the holes 29 before or after dicing the piezoelectric substrate in the step (d). By making the composite substrates 20a after dicing have holes 29 formed therein, the exposed area of the adhesive layer 16 can be increased.

In the above-described embodiment, a support substrate 27 formed of a porous body in which solvent can flow between the joint surface of the support substrate 27 with the piezoelectric substrate 22 and a surface on the side opposite thereto in the step (e) may be prepared as the support substrate 27 in the step (a). By doing so, in the step (e), solvent can reach the adhesive layer 26 through the pores in the support substrate 27, and therefore the contact area between the adhesive layer 26 and solvent in the step (e) is larger. Therefore, in the step (e), the adhesive layer 26 can be removed in a shorter time. Such a porous body can be manufactured, for example, by mixing a base material and a pore forming material formed of a material that is burned by burning, molding the mixture, and then burning the molded mixture. Powders of various ceramic materials, such as aluminum nitride and alumina, can be used as the base material. For example, starch, coke, and foamed resin can be used as the pore forming material.

In the above-described embodiment, electrodes 14 and 15 are formed on the piezoelectric substrate 12 in the step (f). However, the time to form electrodes is not limited to this. For example, the electrode on the first surface of the piezoelectric substrate 12 may be formed at any time after the step (c). Specifically, the electrode on the first surface of the piezoelectric substrate 12 may be formed before or after the formation of the grooves 28 in the step (d). As for the electrode on the second surface of the piezoelectric substrate 12, a piezoelectric substrate 22 on which electrodes are formed in advance may be prepared in the step (a), or electrodes may be formed on the piezoelectric substrate 22 prepared in the step (a) and then the bonding of the step (b) may be performed.

In the above-described embodiment, the piezoelectric device 10 has electrodes. However, the piezoelectric device may be an electrodeless piezoelectric device. The piezoelectric device 10 may be, for example, a radio electrodeless QCM sensor. Such a piezoelectric device is described, for example, in Japanese Unexamined Patent Application Publication No. 2008-26099.

### EXAMPLES

### Example 1

In the step (a), an AT-cut crystal plate (4 inches in diameter and 350 ∝m in thickness) was prepared as a piezoelectric substrate 22. A Si substrate (4 inches in diameter and 230 ∝m in thickness) was prepared as a support substrate 27. The arithmetical mean roughness Ra of a surface of the prepared crystal plate to be joined with the support substrate 27 was 0.1 nm. In the step (b), first, acrylic resin was applied on the surface of the Si substrate using a spin coater (revolutions: 1500 rpm) such that the film thickness was 5000 Å. The crystal plate was joined to the Si substrate with the acrylic resin therebetween, the resin was hardened in an oven at 150° C. so as to form an adhesive layer 26, and a composite substrate 20 was formed.

After the hardening of the resin, in the step (c), a surface of the crystal plate on the side opposite to the joint surface with the Si substrate was ground with a grinder so that the thickness of the crystal plate was 15 ∝m. Further, using diamond slurry (having a particle diameter of 1 ∝m), lap polishing was performed until the thickness of the crystal plate became 5 ∝m. After the lap polishing, using colloidal silica, polishing was performed until the thickness of the crystal plate became 3 ∝m. The surface roughness of the crystal plate at this time was measured using an AFM (Atomic Force Microscope) (measuring range 10 ∝m×10 ∝m). The arithmetical mean roughness Ra was 0.1 nm. The LTV (Local Thickness Variation) of an area of 2 mm×2 mm was measured using a flatness measuring machine using oblique-incidence interferometry. The LTV was 0.05 ∝m on average. As for the PLTV (Percent Local Thickness Variation) at this time, 91.6% met an acceptability criterion of 0.1 ∝m. The film thickness of the crystal plate was measured using a non-contact optical film thickness measuring instrument. The film thickness distribution was ±30 nm within a 4-inch diameter.

After the polishing of the crystal plate, in the step (d), grooves 28 having a width of 100 ∝m and a depth of 5 ∝m were formed using a dicer. The pitch of the grooves 28 was 2 mm. After the formation of the grooves 28, in the step (e), the composite substrate 20 was immersed in potassium hydroxide (KOH) solution of 25 wt % for 30 minutes, the adhesive layer 26 was removed, and crystal single plates (piezoelectric substrates 12) 2 mm long, 2 mm wide, and 3 ∝m thick were detached from and taken out of the support substrate 27. After detachment, the surface roughnesses of both surfaces of the plurality of crystal single plates were measured. The arithmetical mean roughnesses Ra were all about 0.1 nm. This value of arithmetical mean roughness Ra was about the same as the value before the composite substrate 20 was immersed in solvent (potassium hydroxide solution) (described above). The TTVs (Total Thickness Variations) of the plurality of crystal single plates (piezoelectric substrates 12) were measured. Of the plurality of crystal single plates, 90.0% had a TTV not more than 0.1 ∝m (acceptability criterion). That is, this result was about the same as the value of LTV before the composite substrate 20 was immersed in solvent (described above). These values of arithmetical mean roughness Ra and TTV show that when the composite substrate 20 was immersed in this solvent and the adhesive layer 26 was removed, neither surface of the crystal single plates was damaged. After that, in the step (f), Au/Cr electrodes were formed on both surfaces of each crystal single plate, a sensitive film was formed on the surface of one of the electrodes, and QCM sensors as biosensors (piezoelectric devices 10) were made.

### Example 2

In the step (a), a 42°-rotated Y-cut X-propagation LT (LiTaO₃) substrate (4 inches in diameter and 250 ∝m in thickness) was prepared as a piezoelectric substrate 22. A Si substrate (4 inches in diameter and 230 ∝m in thickness) was prepared as a support substrate 27. The arithmetical mean roughness Ra of a surface of the prepared LT substrate to be joined with the support substrate 27 was 0.1 nm. In the step (b), first, epoxy resin was applied on the surface of the Si substrate using a spin coater (revolutions: 1000 rpm) such that the film thickness was 1 ∝m. The LT substrate was joined to the Si substrate with the epoxy resin therebetween, the resin was hardened in an oven at 150° C. so as to form an adhesive layer 26, and a composite substrate 20 was formed.

After the hardening of the resin, in the step (c), a surface of the LT substrate on the side opposite to the joint surface with the Si substrate was ground with a grinder so that the thickness of the LT substrate was 5 ∝m. Further, using diamond slurry (having a particle diameter of 1 ∝m), lap polishing was performed until the thickness of the LT substrate became 2 ∝m. After the lap polishing, using colloidal silica, polishing was performed until the thickness of the LT substrate became 0.2 ∝m. The surface roughness of the LT substrate at this time was measured using an AFM (measuring range 10 ∝m×10 ∝m). The arithmetical mean roughness Ra was 0.1 nm. The LTV (Local Thickness Variation) of an area of 2 mm×2 mm was measured using a flatness measuring machine using oblique-incidence interferometry. The LTV was 0.1 ∝m on average. As for the PLTV (Percent Local Thickness Variation) at this time, 80% met an acceptability criterion of 0.1 ∝m. The film thickness of the LT substrate was measured using a non-contact optical film thickness measuring instrument. The film thickness distribution was ±40 nm within a 4-inch diameter.

After the polishing of the LT substrate, the same steps as the step (d) and step (e) of Example 1 were performed, and LT substrates (piezoelectric substrates 12) 2 mm long, 2 mm wide, and 0.2 ∝m thick were detached from and taken out of the support substrate 27. The arithmetical mean roughnesses Ra of the plurality of LT substrates (piezoelectric substrates 12) after the step (e) were all about 0.1 nm. The TTVs of the plurality of LT substrates were measured. Of the plurality of LT substrates, 80% had a TTV not more than 0.1 ∝m (acceptability criterion). That is, the values of arithmetical mean roughness Ra and TTV of the LT substrates after the step (e) were about the same as the values of arithmetical mean roughness Ra and TTV before the composite substrate 20 was immersed in solvent (described above). After that, in the step (f), an IDT electrode and a reflective electrode were formed on the first surface of each LT substrate, and 1-port SAW resonators (piezoelectric devices 10) were made.

### Comparative Example 1

The same crystal plate as that prepared in the step (a) of Example 1 was prepared, and this crystal single plate was fixed to a surface plate with wax. In this state, the crystal plate was polished in the same way as in the step (c) of Example 1 so that the thickness of the crystal plate was 10 ∝m. After that, heating is performed to 80° C. in order to melt the wax, and the crystal plate was detached from the surface plate. Cracking occurred in the crystal plate owing to the force applied at the time of detachment.

In the manufacturing steps of Examples 1 and 2, cracking did not occur, piezoelectric self-supporting substrates 3 ∝m and 0.2 ∝m thick were obtained, and piezoelectric devices employing these were able to be made. In contrast, in Comparative Example 1, cracking occurred in the piezoelectric substrate even when the thickness was 10 ∝m. Since, in the manufacturing methods of Examples 1 and 2, polishing and division of a piezoelectric substrate are performed in a state joined to a support substrate, after that, an adhesive layer 26 is removed using solvent, and piezoelectric substrates are detached from the support substrate, cracking or the like of the piezoelectric substrate is suppressed, and the piezoelectric substrate can be made thinner.

The present application claims priority from Japanese Patent Application No. 2013-107225 filed on May 21, 2013, the entire contents of which are incorporated herein by reference.

What is claimed is:

1. A method for manufacturing a piezoelectric device, comprising the steps of:
(a) preparing a piezoelectric substrate and a support substrate;
(b) bonding the piezoelectric substrate and the support substrate with an adhesive layer therebetween to form a composite substrate;
(c) polishing a surface of the piezoelectric substrate on the side opposite to a joint surface with the support substrate to thin the piezoelectric substrate;
(d) dicing the composite substrate or half-dicing the composite substrate from the surface of the piezoelectric substrate on the side opposite to the joint surface with the support substrate and thereby dividing the piezoelectric substrate into parts having a size for a piezoelectric device;
(e) immersing the composite substrate after the dicing or the half dicing is performed in solvent, thereby removing the adhesive layer using the solvent, and detaching the piezoelectric substrate from the support substrate; and
(f) obtaining a piezoelectric device using the piezoelectric substrate detached from the support substrate.

2. The method for manufacturing a piezoelectric device according to claim 1,
wherein in the step (d), grooves dividing the piezoelectric substrate into parts having a size for a piezoelectric device are formed by half-dicing the composite substrate from the surface of the piezoelectric substrate on the side opposite to the joint surface with the support substrate, and the adhesive layer is exposed in the grooves,
wherein in the step (e), by immersing the composite substrate after the half dicing is performed in solvent, the adhesive layer is removed using the solvent, and the piezoelectric substrate is detached from the support substrate.

3. The method for manufacturing a piezoelectric device according to claim 1,
wherein in the step (c), polishing is performed until the thickness of the piezoelectric substrate becomes 0.2 ∝m to 5 ∝m.

4. The method for manufacturing a piezoelectric device according to claim 1,
wherein in the step (d), a hole are formed in the support substrate from a surface of the support substrate on the side opposite to a joint surface with the piezoelectric substrate to expose the adhesive layer in the hole.

5. The method for manufacturing a piezoelectric device according to claim 1,
wherein a support substrate formed of a porous body in which the solvent can flow between the joint surface of the support substrate with the piezoelectric substrate and a surface on the side opposite thereto in the step (e) is prepared as the support substrate in the step (a).

6. The method for manufacturing a piezoelectric device according to claim 1,
wherein a surface of the piezoelectric substrate prepared in the step (a) that serves as the joint surface with the support substrate in the step (b) is already mirror-polished, or a surface of the prepared piezoelectric substrate that serves as the joint surface with the support substrate in the step (b) is mirror-polished in the step (a).

7. The method for manufacturing a piezoelectric device according to claim 2,
wherein a surface of the piezoelectric substrate prepared in the step (a) that serves as the joint surface with the support substrate in the step (b) is already mirror-polished, or a surface of the prepared piezoelectric substrate that serves as the joint surface with the support substrate in the step (b) is mirror-polished in the step (a) and wherein in the step (c), polishing is performed until the thickness of the piezoelectric substrate becomes 0.2 ∝m to 5 ∝m.

8. A piezoelectric device manufactured by the method for manufacturing a piezoelectric device according to claim 1.

9. A piezoelectric self-supporting substrate having a thickness of 0.2 ∝m or more and 5 ∝m or less, a length of 0.1 mm or more, a width of 0.1 mm or more, and a TTV (Total Thickness Variation) of 0.1 ∝m or less.

10. The piezoelectric self-supporting substrate according to claim 9, wherein the arithmetical mean roughness Ra of both upper and lower surfaces is 1 nm or less.

11. The piezoelectric self-supporting substrate according to claim 9, wherein the piezoelectric self-supporting substrate is a single crystal substrate.
